(19) United States
(12) Patent Application Publication
(10) Pub. No.: US 2015/0108355 A1
(43) Pub. Date: Apr. 23, 2015

(54) CHARGE SENSITIVE AMPLIFIERS, DETECTORS AND X-RAY PHOTOGRAPHING APPARATUSES INCLUDING THE SAME

(71) Applicant: Samsung Electronics Co., Ltd., Suwon-Si (KR)

(72) Inventors: Kang-Ho LEE, Hwaseong-si (KR); Jin-Myoung KIM, Hwaseong-si (KR); Jae-chul PARK, Yangju-si (KR)

(21) Appl. No.: 14/455,340

(22) Filed: Aug. 8, 2014

(30) Foreign Application Priority Data
Oct. 22, 2013 (KR) 10-2013-0126107

(51) Int. Cl. H04N 5/378; G01N 23/04; G01T 1/208

(52) U.S. Cl. CPC H04N 5/378; G01T 1/208; G01N 23/04
USPC 250/369; 250/370.09; 330/250

(57) ABSTRACT

Disclosed are a charge sensitive amplifier, a detector and an X-ray photographing apparatus including the same. The charge sensitive amplifier includes an amplification unit that amplifies an electric charge input thereto, a capacitor that has one end of the capacitor, connected to an input terminal of the amplification unit, and the other end connected to an output terminal of the amplification unit, and a buffer unit that has an input terminal and an output terminal which is connected to the input terminal of the amplification unit and the one end of the capacitor. Impedance at the input terminal of the buffer unit is lower than impedance at the output terminal of the buffer unit.

### RELATED APPLICATIONS

This application claims priority from Korean Patent Application No. 10-2013-0126107, filed on Oct. 22, 2013, in the Korean Intellectual Property Office, the disclosure of which is incorporated herein in its entirety by reference.

### BACKGROUND

1. Field

Example embodiments relate to charge sensitive amplifiers for amplifying an electric charge and/or detectors and X-ray photographing apparatuses including the same.

2. Description of the Related Art

X-ray is typically used for nondestructive inspection, inspection of a structure and physical properties of a material, image diagnosis, security search, and the like, in various fields such as industry, science, medicine, etc. Generally, an imaging system using X-ray includes an X-ray generator, which emits X-ray, and an X-ray detector, which detects the X-ray passing through an object.

As the X-ray detector, an X-ray detector using a thin film transistor (TFT) is attracting much attention. The X-ray detector outputs, as a digital signal, an X-ray image or a radioscopy which is obtained by using X-ray radiation. The X-ray detector may detect X-rays in a direct type, or directly, or an indirect type, or indirectly.

In the direct type, a photoconductor directly converts X-ray into an electric charge. In the indirect type, a scintillator converts X-ray into visible light, and an optical-to-electrical element such as e.g., a photodiode converts the visible light into an electric charge. The electric charge is converted into a voltage, which is applied to a readout circuit. All electric charges generated by irradiating X-ray should be input to the readout circuit without being lost, but are lost due to a parasitic capacitor of the X-ray detector. In particular, when desiring to acquire an image at a high speed as in a moving image, it is required to increase a moving speed of an electric charge by increasing voltages of both ends of an optical-to-electrical conversion material. However, since impedance of the parasitic capacitor is reduced in a high frequency operation, electric charges are typically lost.

### SUMMARY

Example embodiments relate to charge sensitive amplifiers for expanding an operating frequency band, and/or detectors including the same.

Provided are charge sensitive amplifiers for reducing or preventing a reverse flow of an electric charge, and detectors including the same.

Additional example embodiments will be set forth in part in the description which follows and, in part, will be apparent from the description, or may be learned by practice of the example embodiments.

According to an example embodiment, a charge sensitive amplifier includes an amplification unit that amplifies an electric charge input thereto, a capacitor that has one end thereof connected to an input terminal of the amplification unit, and the other end connected to an output terminal of the amplification unit, and a buffer unit that has an input terminal and an output terminal connected to the input terminal of the amplification unit and to the one end of the capacitor, wherein the impedance at the input terminal is lower than the impedance at the output terminal.

The buffer unit may include a common-gate amplifier.

An input terminal of the common-gate amplifier may be the input terminal of the amplification unit.

An output terminal of the common-gate amplifier may be connected to the input terminal of the amplification unit and the one end of the capacitor.

The charge sensitive amplifier may further include at least one of: a first constant current source that is connected to the input terminal of the common-gate amplifier, and a second constant current source that is connected to the output terminal of the common-gate amplifier.

The amplification unit may include an operational amplifier.

An input terminal of the operational amplifier may include an inverting input terminal and a non-inverting input terminal, a voltage difference between the inverting input terminal and the non-inverting input terminal being output as a voltage.

An electric charge may be input through the inverting input terminal, and the non-inverting input terminal may be connected to a reference voltage.

The charge sensitive amplifier may further include a switch that has one end, connected to the input terminal of the amplification unit and the one end of the capacitor, and the other end connected to the output terminal of the amplification unit and the other end of the capacitor.

When the switch is turned off, the electric charge applied to the amplification unit may be output as a voltage, and when the switch is turned on, the electric charge applied to the amplification unit may be discharged.

According to another example embodiment, a detector includes the charge sensitive amplifier and a charge generator that generates an electric charge according to a stimulus, and applies the electric charge to the amplification unit.

The stimulus may be X-ray radiation.

At a first frequency band, the impedance at the input terminal may be lower than the impedance caused by a parasitic capacitor of the detector.

The charge generator may include a photoconductor that converts incident light into an electric charge.

The charge generator may include a scintillator configured to convert incident light into visible light and a photodiode configured to convert the visible light into an electric charge.

The detector may further include a comparator that compares a voltage, output from the amplification unit, and a reference voltage to output a pulse signal.

The detector may further include a counter unit that counts number of signals output from the comparator.

According to another example embodiment, an X-ray photographing apparatus includes the charge sensitive amplifier and a charge generator that generates an electric charge with X-ray, and applies the electric charge to the amplification unit.

The X-ray photographing apparatus may further include an X-ray source that generates X-ray radiation.

### BRIEF DESCRIPTION OF THE DRAWINGS

These and/or other example embodiments will become apparent and more readily appreciated from the following description, taken in conjunction with the accompanying drawings in which:

FIG. 1 is a block diagram schematically illustrating an X-ray photographing apparatus according to an example embodiment;

FIG. 2 is a diagram schematically illustrating a partial appearance of the X-ray photographing apparatus according to an example embodiment;

FIG. 3 is a block diagram schematically illustrating an X-ray detector according to an example embodiment;

FIG. 4 is a reference diagram for describing a parasitic capacitor of the X-ray detector according to an example embodiment;

FIG. 5 is a diagram illustrating a detailed example embodiment of the X-ray detector of FIG. 1;

FIGS. 6A and 6B are diagrams showing a simulation result of a flow of a current applied to a charge sensitive amplifier according to whether there is a buffer unit;

FIG. 7A shows a result obtained by simulating an output waveform of a charge sensitive amplifier including no buffer unit, according to a comparative example;

FIG. 7B shows a result obtained by simulating an output waveform of a charge sensitive amplifier including the buffer unit, according to an example embodiment; and

FIGS. 8 to 11 are respective diagrams schematically illustrating X-ray detectors according to another example embodiment.

### DETAILED DESCRIPTION

Reference will now be made in detail to example embodiments illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain the present description. Expressions such as “at least one of,” when preceding a list of elements, modify the entire list of elements and do not modify the individual elements of the list.

In the drawings, like reference numerals refer to like elements throughout, and the size of each element may be exaggerated for clarity and convenience of description.

Moreover, the term “ . . . unit” described in specification denotes an element for performing at least one function or operation, and may be implemented in hardware, software or the combination of hardware and software.

The term “object” used herein may include a person, an animal, a part of the person, or a part of the animal. For example, an object may include an organ such as a liver, a heart, a womb, a brain, breasts, an abdomen, or the like, or a blood vessel, but is not limited thereto. Also, the term “user” used herein is a medical expert, and may be a doctor, a nurse, a medical technologist, a medical image expert, or the like, or may be an engineer repairing a medical apparatus. However, the user is not limited thereto.

It will be understood that when an element is referred to as being “on,” “connected” or “coupled” to another element, it can be directly on, connected or coupled to the other element or intervening elements may be present. In contrast, when an element is referred to as being “directly on,” “directly connected” or “directly coupled” to another element, there are no intervening elements present. As used herein the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain example embodiments of the present description.

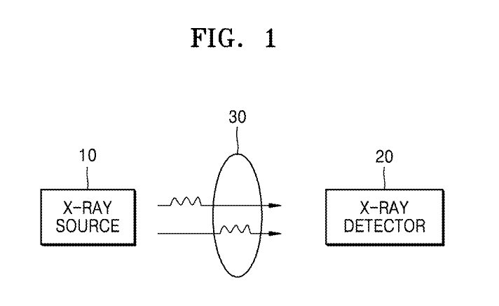

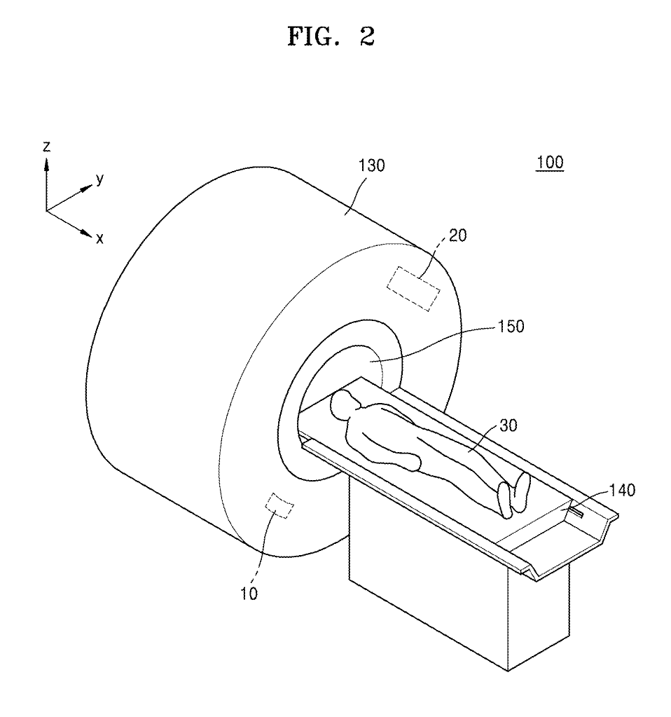

FIG. 1 is a block diagram schematically illustrating an X-ray photographing apparatus according to an example embodiment, and FIG. 2 is a diagram schematically illustrating a partial appearance of the X-ray photographing apparatus according to an example embodiment . As illustrated in FIGS. 1 and 2, the X-ray photographing apparatus may include an X-ray source 10, which is configured to emit X-ray, and an X-ray detector 20, which is configured to detect the X-ray passing through an object 30. In the X-ray photographing apparatus according to an example embodiment, a plurality of the X-ray sources 10 may be arranged in an array type. The plurality of X-ray sources 10 may be arranged one-dimensionally or two-dimensionally. Also, a plurality of the X-ray detectors 20 may be arranged in an array type. The plurality of X-ray detectors 20 may also be arranged one-dimensionally or two-dimensionally.

The plurality of X-ray sources 10 may be separately driven or controlled to emit X-ray radiation. Therefore, all the X-ray sources 10 may be driven or controlled to irradiate X-rays onto the object 30, or some of the X-ray sources 10 may be driven or controlled to irradiate X-rays onto the object 30. Also, at least one X-ray source 10 may be driven or controlled to irradiate X-ray onto all regions or a specific region of the object 30. In addition, at least one or more of the X-ray sources 10 may be driven or controlled simultaneously, contemporaneously or sequentially. In this case, only the X-ray detector 20 corresponding to the driven X-ray source 10 may be driven or controlled.

According to the example embodiment illustrated in FIG. 2, the X-ray photographing apparatus 100 may further include a gantry 130 and an examination table 140. The gantry 130 includes a cylindrical opening 150 disposed at a central portion thereof, and the object 30 is inserted into the opening 150. Also, the X-ray source 10 emitting X-ray and the X-ray detector 20 detecting the X-ray passing through the object 30 may be disposed in the gantry 130. The object 30 may be located at the center of a certain region of the opening 150 of the gantry 130, and the X-ray source 10 may be disposed opposite to the X-ray detector 20, with the object 30 being disposed therebetween during operation of the apparatus 100. For example, the X-ray source 10 and the X-ray detector 20 are included in the gantry 130 in a structure that vertically irradiates X-ray radiation.

According to at least one example embodiment, while the gantry 130 is rotating around the object 30 at 360 degrees, or a certain degree, by using a gantry driver (not shown), the X-ray source 10 and the X-ray detector 20 may photograph the object 30 at various angles as a result. Also, the gantry driver may horizontally move back and forth, namely, move on the x-axis, such that a photographing part of the object 30 lying on the examination table 140 is located at the internal center of the gantry 130.

The examination table 140 is provided as a bed type having a certain width such that a patient (i.e., the object 30) lies on the examination table 140 in a fixed position. An examination table driver (not shown), which transfers the examination table 140 to the opening 150 included in the central portion of the gantry 130, may be provided in a region of the examination table 140. The examination table 140 may be horizontally, i.e., along the x direction, moved back and forth by the examination table driver such that a photographing part of the object 30 is located at the internal center of the gantry 130. The examination table driver may also move the examination table 140 in a vertical direction (i.e., a z-axis direction) or in a lateral direction (i.e., a y-axis direction) so as to acquire a clear image. In FIG. 2, a computed tomography (CT) apparatus is illustrated as an example of the X-ray photographing apparatus 100. However, the X-ray photographing apparatus is not limited thereto. The examination table 140 may be applied to all photographing apparatuses using X-ray as a source.

In addition, the X-ray photographing apparatus 100 may further include a signal processor that acquires an image by using a detection result of the X-ray detector 20, a display unit that displays the image, and an input unit that receives a user command. The elements are considered known technologies, and thus, their detailed descriptions are not provided.

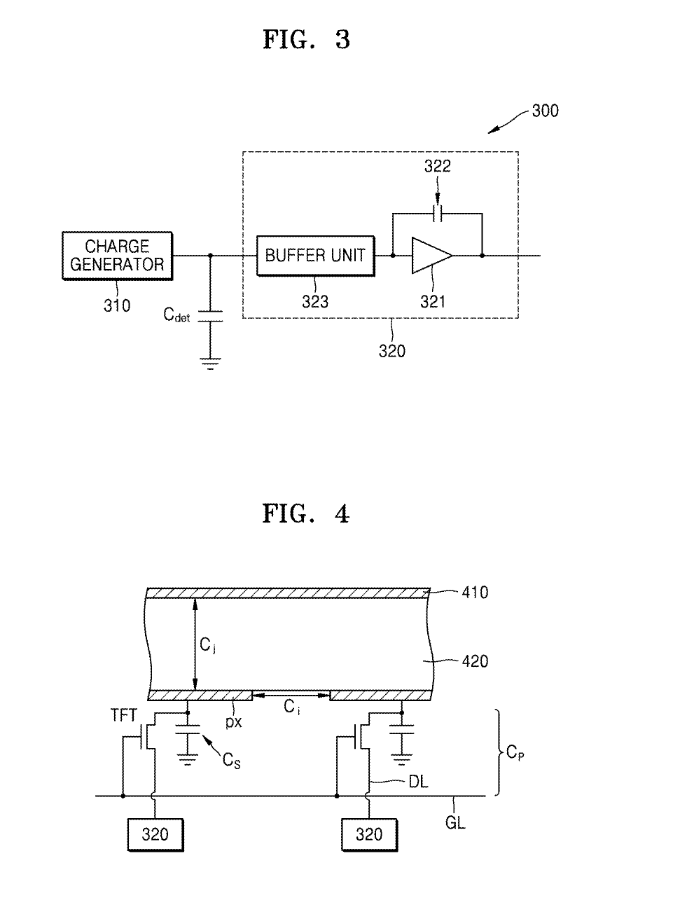

FIG. 3 is a block diagram schematically illustrating an X-ray detector according to an example embodiment. As illustrated in FIG. 3, the X-ray detector 20 may include a charge generator 310, which generates an electric charge according to the X-ray radiation applied thereto, and a charge sensitive amplifier 320 that outputs a voltage corresponding to the electric charge generated from the charge generator 310.

The charge generator 310 may directly convert the X-ray, which is incident thereon, into an electric charge. Alternatively, the charge generator 310 may convert the X-ray into visible light, and convert the visible light into an electric charge. When an electric charge is generated by the former type, the charge generator 310 may include a photoconductor. When an electric charge is generated by the latter type, the charge generator 310 may include a scintillator, which converts the X-ray into visible light, and a photodiode that converts the visible light into the electric charge. Also, the charge generator 310 may generate an electric charge by using both of the former type and the latter type.

The charge sensitive amplifier 320 amplifies the electric charge generated from the charge generator 310 to output a voltage. The charge sensitive amplifier 320 may include an amplification unit 321 that receives the electric charge, generated by the charge generator 310, through an input terminal, and amplifies the electric charge to output an amplified voltage through an output terminal. Also, the charge sensitive amplifier 320 may further include a capacitor 322 and a buffer unit 323.

One end of the capacitor 322 may be connected to the input terminal of the amplification unit 321, and the other end may be connected to the output terminal of the amplification unit 321. Therefore, the electric charge generated by the charge generator 310 may be stored in the capacitor 322. The stored electric charge may be amplified by the amplification unit 321, and may be output as a voltage.

Moreover, the charge sensitive amplifier 320 may further include a buffer unit 323 that is disposed between the charge generator 310 and the amplification unit 321. In detail, an input terminal of the buffer unit 323 may be connected to the charge generator 310, and an output terminal of the buffer unit 323 may be connected to the input terminal of the amplification unit 321 and to one end of the capacitor 322. The impedance at the input terminal of the buffer unit 323 may be lower than the impedance at the output terminal of the buffer unit 323. Therefore, the electric charge is easily applied from the charge generator 310 to the charge sensitive amplifier 320, but a leakage of the electric charge from the charge generator 310 to the charge sensitive amplifier 320 is reduced or prevented. The buffer unit 323 substantially prevents the impedance of the charge sensitive amplifier 320 from becoming higher than the impedance caused by a parasitic capacitor Cdet.

FIG. 4 is a reference diagram for describing a parasitic capacitor of the X-ray detector according to an example embodiment. The X-ray detector 20 illustrated in FIG. 4 includes a photoconductor. Such a configuration is only for convenience of description, and the example embodiment is not limited thereto. The X-ray detector 20 may include a common electrode 410 and a plurality of pixel electrodes PX that are separated from each other in correspondence with the common electrode 410. The X-ray detector 20 may further include a storage capacitor Cs, which is connected to a corresponding pixel electrode PX, and a transistor TFT that is connected to the corresponding pixel electrode PX in parallel with the storage capacitor Cs. A gate of the transistor TFT may be connected to a gate line GL, and the transistor TFT may be connected to the charge sensitive amplifier 320 through a data line DL.

A photoconductor 420 may be disposed between the common electrode 410 and the pixel electrode PX. The photoconductor 420 may include a material which density is increased by light, and in which a hole-electron pair is generated by incident light. For example, the photoconductor 420 may be formed of, or include one or more of CdS, PbS, TiPb₂, HgI₂, PbI₂, a-Se, a-Si, and p-Si.

For example, when a positive voltage is applied to the common electrode 410, an electron generated from the incident X-ray moves to the common electrode 410, and a hole generated from the incident X-ray moves to the pixel electrode PX, thereby allowing an electric charge to be stored in the storage capacitor Cs. When the transistor TFT is turned on in response to a signal transferred through the gate line GL, the electric charge stored in the storage capacitor Cs may be applied to the charge sensitive amplifier 320.

A plurality of parasitic capacitors Cdet may be formed in the X-ray detector 20, and may include a first parasitic capacitor Cj between the common electrode 410 and the pixel electrode PX, a second parasitic capacitor Ci between adjacent pixel electrodes PX, and a third parasitic capacitor Cp between adjacent electrode pads such as the transistor TFT and the like. The parasitic capacitor Cdet has high impedance at a low frequency band, and when the transistor TFT is turned on, most of a plurality of the electric charges stored in the storage capacitor Cs may be applied to the charge sensitive amplifier 320. However, as an operating frequency increases, the impedance of the parasitic capacitor Cdet becomes lower, and the impedance of the charge sensitive amplifier 320 becomes higher. Therefore, there is a possibility that the electric charge stored in the storage capacitor Cs is applied to the parasitic capacitor Cdet. As a result, in the charge sensitive amplifier 320 according to an example embodiment, the buffer unit 323 having a low impedance is connected to the input terminal of the charge sensitive amplifier 320.

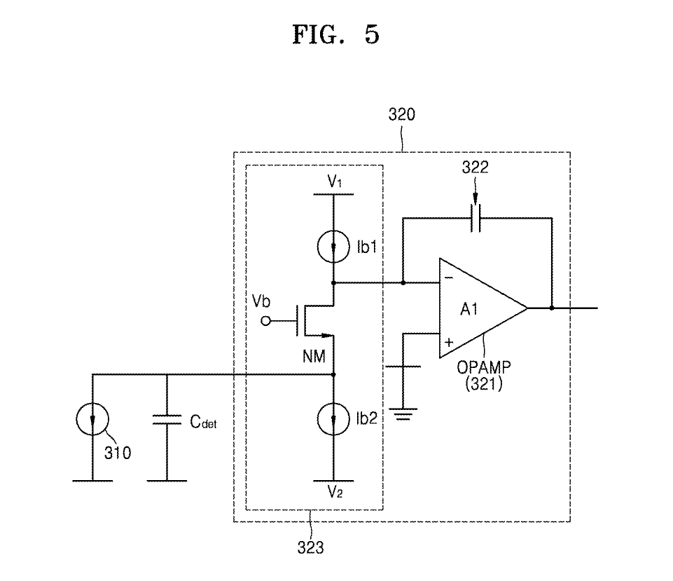

FIG. 5 is a diagram illustrating a detailed embodiment of the X-ray detector 20 of FIG. 1. As illustrated in FIG. 5, the amplification unit 321 of the charge sensitive amplifier 320 may be implemented with an operational amplifier OPAMP, and the buffer unit 323 may be implemented with a common-gate amplifier. In this case, the input terminal of the amplification unit 321 may include an inverting input terminal (−) and a non-inverting input terminal (+), and output a voltage generated by amplifying a voltage difference between the inverting input terminal (−) and the non-inverting input terminal (+).

The inverting input terminal (−) of the amplification unit 321 may be connected to an output terminal of the common-gate amplifier 323. An input terminal of the common-gate amplifier 323 may be connected to the charge generator 310. In detail, the common-gate amplifier 323 may include an NMOS transistor. A source of the NMOS transistor is the input terminal of the charge sensitive amplifier 320, and receives the electric charge from the charge generator 310. When a bias voltage is applied to a gate of the NMOS transistor, the electric charge received from the input terminal of the charge sensitive amplifier 320 is amplified and is output to a drain of the NMOS transistor. The drain of the NMOS transistor is the output terminal of the buffer unit 323. Also, a first constant current source Ib1 may be connected to the source of the NMOS transistor, and a second constant current source Ib2 may be connected to the drain of the NMOS transistor. Input impedance may be adjusted by adjusting a current of each of the first and second constant current sources Ib1 and Ib2 and a size, for example, a width or a length, of the NMOS transistor. The common-gate amplifier 323 may be implemented with a resistor instead of the first and second constant current sources Ib1 and Ib2.

The common-gate amplifier 323 has a low impedance at the input terminal thereof, but has a high impedance at the output terminal thereof. When the impedance at the input terminal is lower than the impedance caused by the parasitic capacitor, the electric charge generated by the charge generator 310 may be applied to the charge sensitive amplifier 320. As described above, by adding the buffer unit 323 into the charge sensitive amplifier 320, the charge sensitive amplifier 320 substantially prevents the electric charge from being leaked to the parasitic capacitor.

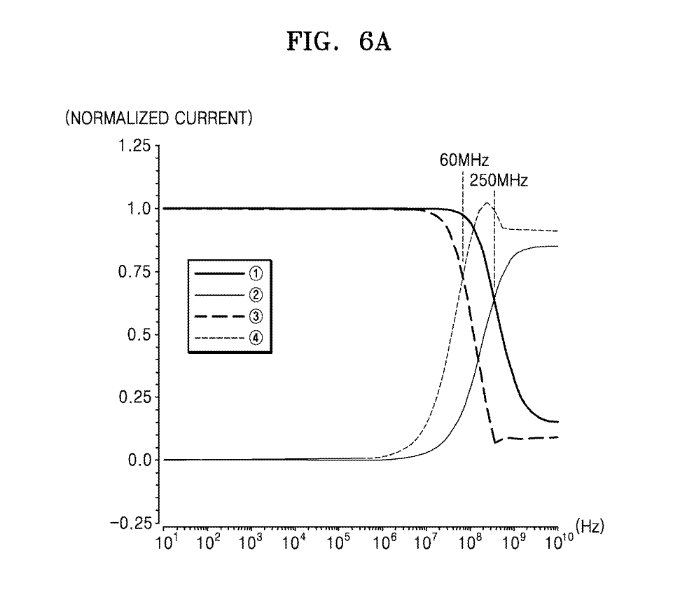

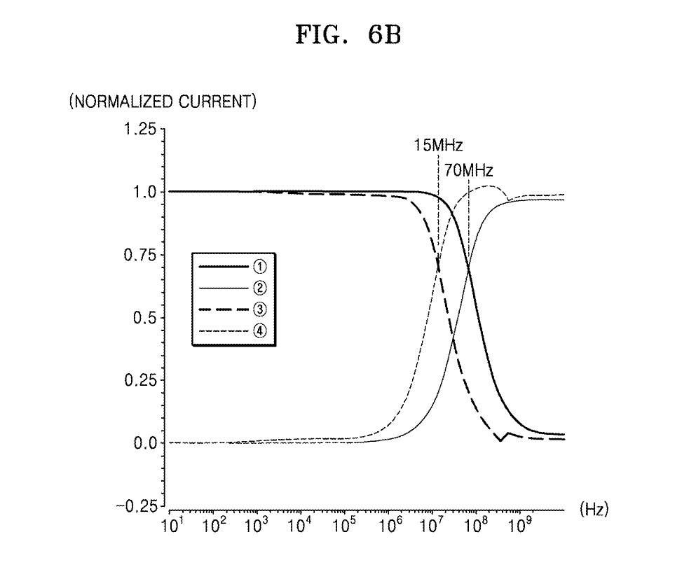

FIGS. 6A and 6B are diagrams showing a simulation result of a flow of a current applied to a charge sensitive amplifier according to whether there is a buffer unit. The impedance of a parasitic capacitor is set to 100 fF (femtoFarad, 10⁻¹⁵ F). In FIGS. 6A and 6B, \textcircled{1} indicates a current value that is applied to a charge sensitive amplifier including a buffer unit, \textcircled{2} indicates a current value that is applied from the charge sensitive amplifier including the buffer unit to the parasitic capacitor, \textcircled{3} indicates a current value that is applied to a charge sensitive amplifier including no buffer unit, and \textcircled{4} indicates a current value that is applied from the charge sensitive amplifier including no buffer unit to the parasitic capacitor.

As shown in FIG. 6A, in the charge sensitive amplifier including no buffer unit, an inverse current occurs at about 60 MHz. That is, a current applied to the parasitic capacitor becomes equal to a current applied to the charge sensitive amplifier at about 60 MHz, and a larger amount of current flows to the parasitic capacitor at a frequency domain higher than 60 MHz. However, in the charge sensitive amplifier including the buffer unit, an inverse current occurs at about 250 MHz higher than 60 MHz. In FIG. 6B, impedance caused by the parasitic capacitor is set to 500 fF. In the charge sensitive amplifier including no buffer unit, an inverse current occurs at about 15 MHz. On the other hand, in the charge sensitive amplifier including the buffer unit, an inverse current occurs at about 70 MHz higher than 15 MHz. As a result, an operating frequency range may be expanded by the buffer unit. In FIGS. 6A and 6B, a numerical value of simulation may be changed according to a capacitance value of the parasitic capacitor and a performance of the charge sensitive amplifier. However, it can be seen that the operating frequency range is expanded by the buffer unit.

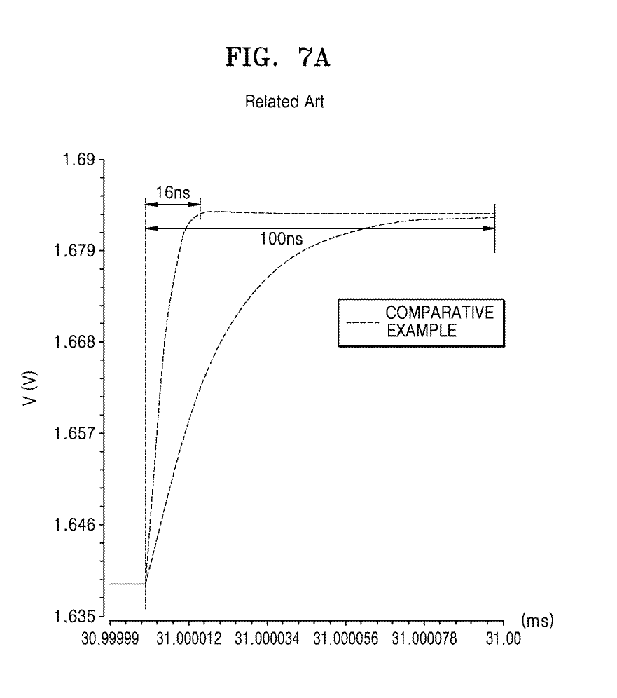

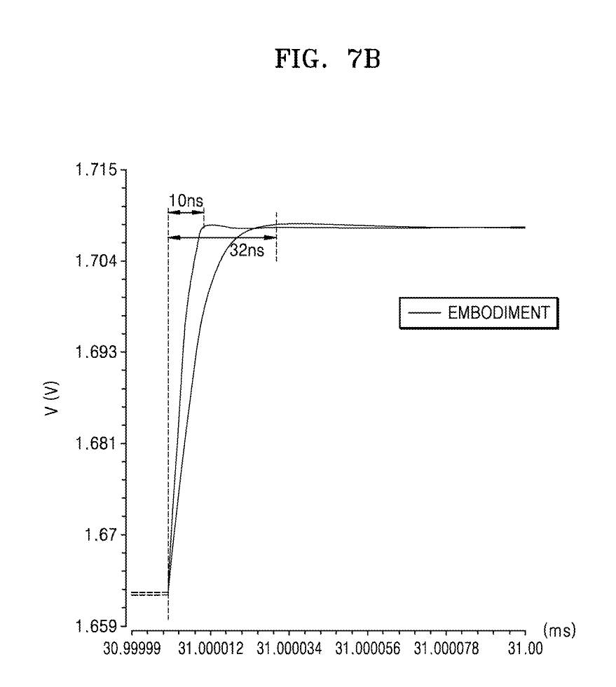

FIG. 7A shows a result obtained by simulating an output waveform of a charge sensitive amplifier including no buffer unit, according to a comparative example, and FIG. 7B shows a result obtained by simulating an output waveform of a charge sensitive amplifier including the buffer unit, according to an example embodiment. As shown in FIG. 7A, when impedance caused by the parasitic capacitor is about 1 pF, a charge sensitive amplifier including no buffer unit outputs a voltage after about 100 ns elapses. When impedance caused by the parasitic capacitor is about 100 pF, the charge sensitive amplifier including no buffer unit outputs a voltage after about 16 ns elapses. However, as shown in FIG. 7B, when impedance caused by the parasitic capacitor is about 1 pF, a charge sensitive amplifier including the buffer unit outputs a voltage after about 32 ns elapses. When impedance caused by the parasitic capacitor is about 100 pF, the charge sensitive amplifier including the buffer unit outputs a voltage after about 10 ns elapses. In FIGS. 7A and 7B, a numerical value of simulation may be changed according to a capacitance value of the parasitic capacitor and a performance of the charge sensitive amplifier. As described above, in the charge sensitive amplifier including the buffer unit, it can be seen that a leakage current is low at a fast operating frequency band, and thus, relatively more electric charges are applied to the charge sensitive amplifier. Also, it can be seen that a delay time is shortened because more electric charges are applied to the charge sensitive amplifier including the buffer unit. Due to a fast response time of the charge sensitive amplifier according to an example embodiment, it is possible to detect X-ray at a high speed.

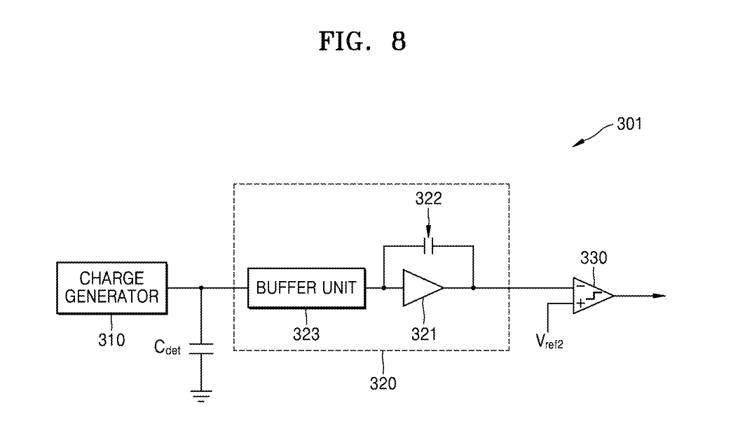

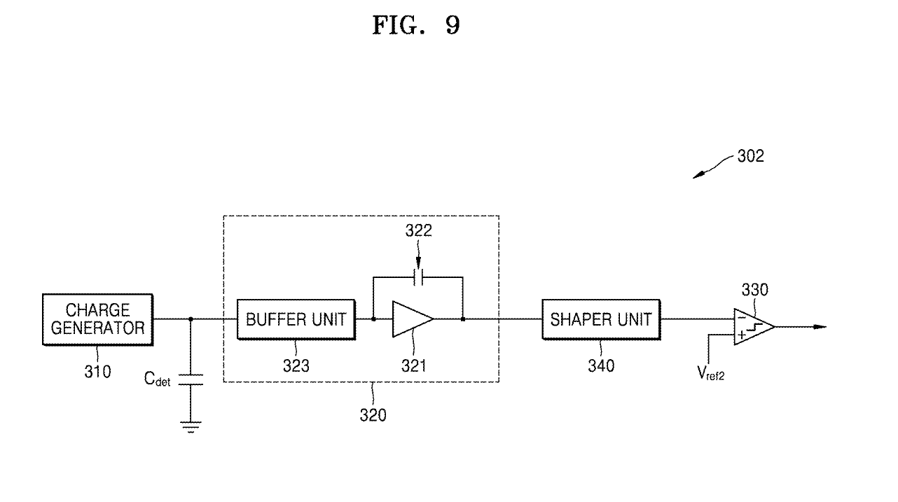

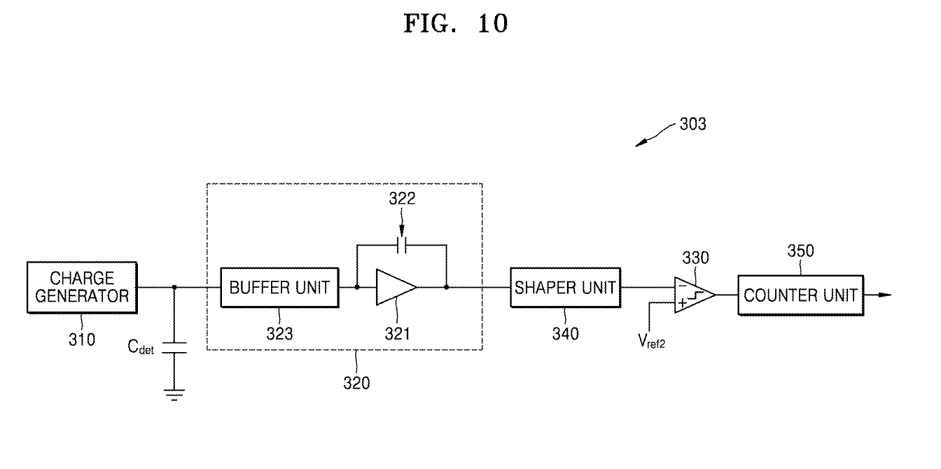

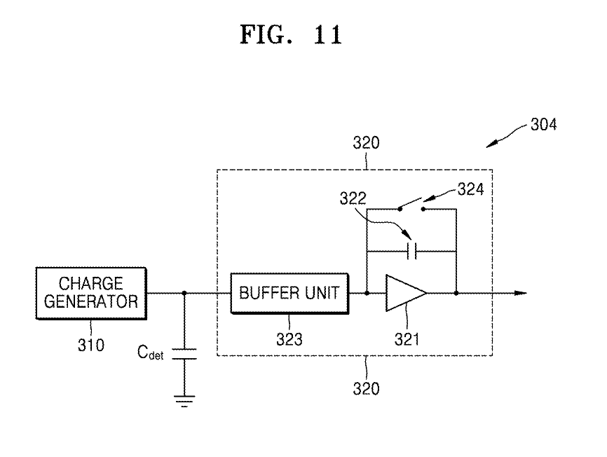

FIGS. 8 to 11 are respective diagrams schematically illustrating X-ray detectors according to another example embodiment. In comparison with FIG. 3, an X-ray detector 301 of FIG. 8 further includes a comparator 330, an X-ray detector 302 of FIG. 9 further includes a comparator 330 and a shaper unit 340, and an X-ray detector 303 of FIG. 10 further includes a comparator 330, a shaper unit 340, and a counter unit 350.

The comparator 330 may compare a voltage, output from the charge sensitive amplifier 320, with a desired, or alternatively predetermined reference voltage Vref2 to output a comparison result. An output voltage generated through amplification by the charge sensitive amplifier 320 may be applied to a positive (+) terminal of the comparator 330. The comparator 330 may compare an output voltage of the charge sensitive amplifier 320 with the reference voltage Vref2 to output a pulse signal having a pulse width until the output voltage becomes higher than the reference voltage Vref2 and then becomes lower than the reference voltage Vref2.

The X-ray detector 302, as illustrated in FIG. 9, may further include the shaper unit 340. The shaper unit 340 is configured to readjust the shape of a voltage so that the voltage output from the charge sensitive amplifier 320 is recognized by the comparator 330. For example, the shaper unit 340 may filter out noise.

Moreover, the X-ray detector 303 has a photo counting scheme, and as illustrated in FIG. 10, may further include the counter unit 350. The counter unit 350 counts the number of pulses of the pulse signal output from the comparator 330. The pulse signal is output each time a photon corresponding to X-ray is incident, an amount of energy which is obtained from the X-ray incident onto the charge generator 310 per unit time may be substantially the same as the number of pulses of the pulse signal. The counter unit 350, for example, may be implemented with a linear feedback shift register or a binary counter.

Moreover, as illustrated in FIG. 11, the X-ray detector 304 may further include a switch 324. One end of the switch 324 may be connected to the input terminal of the amplification unit 321, and the other end may be connected to the output terminal of the amplification unit 321.

When an electric charge is applied to the amplification unit 321 with the switch 324 being turned off, the electric charge is stored in the capacitor 322, and the amplification unit 321 amplifies the stored electric charge to output a voltage. On the other hand, when the switch 324 is in turned on, the electric charge stored in the capacitor 322 is discharged. That is, when the switch 324 is turned on, the input terminal and output terminal of the amplification 321 are short-circuited.

As described above, when the switch 324 is turned off, the voltage corresponding to the electric charge is output, and when the switch 324 is turned on, the electric charge is discharged. Therefore, the charge sensitive amplifier 320 may output only an electric charge which is used for an image.

As described above, according to the one or more of the above example embodiments, the charge sensitive amplifier and the detector including the same according to an example embodiment operate at a broad operating frequency band.

The example charge sensitive amplifier and the example detector including the same operate at a high frequency band, and thus, a charge amplification and detection speed becomes faster.

The example charge sensitive amplifier and the example detector including the same reduce or prevent a reverse flow of a current, thus reducing or preventing noise.

The X-ray photographing apparatus including the example charge sensitive amplifier or the example detector can photograph an object at a high speed.

It should be understood that the example embodiments described therein should be considered in a descriptive sense only and not for purposes of limitation. Descriptions of features within each example embodiment should typically be considered as available for other same or similar features or aspects in other example embodiments.

While one or more example embodiments have been described with reference to the figures, it will be understood by those of ordinary skill in the art that various changes in form and details may be made therein without departing from the spirit and scope defined by the following claims.

What is claimed is:

1. A charge sensitive amplifier comprising:
an amplification unit configured to amplify an electric charge input thereto;
a capacitor having one end connected to an input terminal of the amplification unit, and the other end connected to an output terminal of the amplification unit; and
a buffer unit that has an input terminal and an output terminal connected to the input terminal of the amplification unit and to the one end of the capacitor, wherein an impedance at the input terminal of the buffer unit is lower than an impedance at the output terminal of the buffer unit.

2. The charge sensitive amplifier of claim 1, wherein the buffer unit comprises a common-gate amplifier.

3. The charge sensitive amplifier of claim 2, wherein an input terminal of the common-gate amplifier is the input terminal of the amplification unit.

4. The charge sensitive amplifier of claim 3, wherein an output terminal of the common-gate amplifier is connected to the input terminal of the amplification unit and to the one end of the capacitor.

5. The charge sensitive amplifier of claim 4, further comprising at least one of:
a first constant current source connected to the input terminal of the common-gate amplifier; and
a second constant current source connected to the output terminal of the common-gate amplifier.

6. The charge sensitive amplifier of claim 1, wherein the amplification unit comprises an operational amplifier.

7. The charge sensitive amplifier of claim 6, wherein an input terminal of the operational amplifier comprises an inverting input terminal and a non-inverting input terminal, a voltage difference between the inverting input terminal and the non-inverting input terminal being output as a voltage.

8. The charge sensitive amplifier of claim 7, wherein,
an electric charge is input through the inverting input terminal, and
the non-inverting input terminal is connected to a reference voltage.

9. The charge sensitive amplifier of claim 1, further comprising a switch having one end connected to the input terminal of the amplification unit and to the one end of the capacitor, and another end connected to the output terminal of the amplification unit and to the other end of the capacitor.

10. The charge sensitive amplifier of claim 9, wherein,
when the switch is turned off, the electric charge applied to the amplification unit is output as a voltage, and
when the switch is turned on, the electric charge applied to the amplification unit is discharged.

11. A detector comprising:
the charge sensitive amplifier of claim 1; and
a charge generator configured to generate an electric charge according to a stimulus, and configured to apply the electric charge to the amplification unit.

12. The detector of claim 11, wherein the stimulus is X-ray radiation.

13. The detector of claim 11, wherein at a first frequency band, an impedance at the input terminal of the buffer unit is lower than an impedance caused by a parasitic capacitor of the detector.

14. The detector of claim 11, wherein the charge generator comprises a photoconductor configured to convert incident light into an electric charge.

15. The detector of claim 11, wherein the charge generator comprises:
a scintillator configured to convert incident light into visible light; and
a photodiode configured to convert the visible light into an electric charge.

16. The detector of claim 1, further comprising a comparator configured to compare a voltage output from the amplification unit and a reference voltage to output a pulse signal.

17. The detector of claim 1, further comprising a counter unit configured to count a number of signals output from the comparator.

18. An X-ray photographing apparatus comprising:
the charge sensitive amplifier of claim 1; and
a charge generator configured to generate an electric charge as a result of incident X-ray radiation, and configured to apply the electric charge to the amplification unit.

19. The X-ray photographing apparatus of claim 18, further comprising an X-ray source configured to generate the X-ray radiation.
